(19) United States
(12) Patent Application Publication
(10) Pub. No.: US 2009/0159315 A1
(43) Pub. Date: Jun. 25, 2009

(54) Wiring substrate

(75) Inventor: Atsuhisa Fukuoka, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/314,435

(22) Filed: Dec. 10, 2008

(30) Foreign Application Priority Data
Dec. 19, 2007 (JP) 327137/2007

(51) Int. Cl. H05K 7/20

(52) U.S. Cl. 174/252

(57) ABSTRACT

Disclosed herewith is a wiring substrate for releasing a heat generated by an electronic part efficiently through a heat pipe. The wiring substrate of the present invention includes a built-in heat pipe. The substrate also has amounting area. In the mounting area, an IC chip is mounted on a mounting surface. The substrate has a heat pipe formed so that its distance from the mounting area with respect to the mounting surface becomes shorter than its distance from an outside area provided outside the mounting area.

### FIELD OF THE INVENTION

The present invention relates to a wiring substrate, particularly to a wiring substrate (hereinafter, to be referred to simply as the substrate) provided with a heat pipe.

### BACKGROUND OF THE INVENTION

In recent years, it has been difficult for the conventional techniques of the cooling systems of semiconductor integrated circuits (hereinafter, to be referred to as IC chips) to cope with heat radiation that has increased more and more due to the increase of the heating values of IC chips, which have been caused by the improvement of the operation frequencies of those IC chips. The conventional techniques have employed natural heat radiation to be made from the surfaces of those IC chips. And those technique have just prompted heat conduction from the GND terminals of those IC chips to their GND layers formed on their substrates respectively. Furthermore, it has also been seen lately that the number of I/O elements required to realize the functions of those IC chips has increased and the number of those I/O elements in each IC chip mounted package has come to be far more than the number of power supply terminals and GND terminals of the IC chip. And accordingly, the power consumption of such I/O elements has also been increasing. This is why the conventional cooling systems of those IC chips have come to be difficult to cope with such heat radiation. And this is why more efficient heat radiation systems have been required for such IC chips.

One of the most popular methods for releasing the heat from an IC chip that requires such efficient heat radiation is disclosed by JP-A-Hei4 (1992)-133451, which uses heat radiation fins attached to the object IC package. FIG. 7 shows an IC package described in the patent document 1. As shown in FIG. 7, an IC chip 1 is mounted on a surface of a ceramic wiring structure 2. And on the back surface of the structure 2, on which the IC chip 1 is mounted, is a heat sink 3 such as an element having heat radiation fins or the like. The method secures a sufficient area for the heat sink within a range that never exceeds the allowable loss of the IC chip package. Consequently, the heat comes to be released outside the package more efficiently, thereby the heat radiation characteristics of the IC chip package is improved.

As such a heat radiation system, there are some well-known ones disclosed in, for example, JP-A-Hei6 (1994)-291481 and JP-A-Hei6 (1994)-152172. In each of these patent documents, a heat radiation pipe system is provided in the object IC chip mounted substrate. The heat pipe means a heat conduction element used for releasing an object heat by flowing a coolant such as a liquid, gas, or the like therein for heat radiation. As shown in FIG. 8, the circuit substrate described in the patent document 2 includes a printed circuit substrate 5 adhered to the front surface of a heat radiation plate 4 and a heat pipe 6 provided on the back surface of the heat radiation plate 4. And as shown in FIG. 9, the circuit substrate 7 described in the patent document 3 has a circuit pattern 8 on its top surface and a heat radiation plate 9 on its back surface. And the heat pipe 10 is in contact with this heat radiation plate 9. In each of the patent documents 2 and 3, a heat pipe is used in such a way to flow a coolant in a dedicated area provided in a specific area in the substrate. There is also another related heat releasing technique described in JP-A-2002-327993. According to the method disclosed in the patent document 4, thin plates 13 and 14 having a plurality of holes 11 and 12 respectively are put one upon another as shown in FIG. 10 to form a thin pipe 15 used for releasing a heat generated from an object IC chip. The thin pipe has the same functions as those of the heat pipes disclosed in JP-A-Hei6 (1994)-291481 and JP-A-Hei6 (1994)-152172, respectively.

### SUMMARY OF THE INVENTION

As described above, in case of the method disclosed in each of the patent documents 2 and 3, a heat pipe is used to make heat radiation from each IC chip mounted on the surface of the substrate. However, if the structure in the substrate is a multilayer one consisting of conductor layers and insulation layers disposed alternately, the heat radiation from the IC chip mounted substrate surface comes to be disturbed by such a layer as an insulation layer having different heat conductivity (having lower heat conductivity). To avoid this trouble, therefore, in case of such a substrate having a multilayer structure consisting of conductor layers and insulation layers disposed alternately, the heat transmitted from the GND terminal of the subject IC chip comes to be dominant over the heat radiation through the heat pipe, thereby effective heat radiation is impossible.

Under such circumstances, it is an object of the present invention to provide a wiring substrate having a built-in heat pipe. The wiring substrate also has an electronic part mounting area provided on its one main surface and a heat pipe formed so that its distance from the mounting area with respect to the one main surface becomes shorter than its distance from an area provided outside the mounting area. The wiring substrate can thus release the heat generated from the electronic part satisfactorily.

According to the present invention, because the heat pipe provided in the wiring substrate is disposed so as to be closer to the surface around the electronic part mounting surface and deeper from the surface at the periphery of the electronic part mounting surface, the heat pipe can release the heat generated from the electronic part efficiently.

### BRIEF DESCRIPTION OF THE DRAWINGS

FIG. 1 is a top view of an IC chip mounted substrate in an embodiment of the present invention;

FIG. 2A is a cross sectional view of a configuration of the IC chip mounted substrate in the embodiment of the present invention;

FIG. 2B is another cross sectional view of the configuration of the IC chip mounted substrate in the embodiment of the present invention;

FIG. 2C is still another cross sectional view of the configuration of the IC chip mounted substrate in the embodiment of the present invention;

FIG. 3 is a cross sectional view of another configuration of the substrate on which vias are formed under pads respectively in the embodiment of the present invention;

FIG. 4 is a cross sectional view of still another configuration of the substrate on which through-vias are formed in the embodiment of the present invention;

FIG. 5 is a cross sectional view of still another configuration of the substrate on which two IC chips are mounted in the embodiment of the present invention;

FIG. 6 is another cross sectional view of the configuration of the substrate on which two IC chips are mounted in the embodiment of the present invention;

FIG. 7 is a cross sectional view of a configuration of a conventional substrate;

FIG. 8 is a perspective view of the configuration of the conventional substrate;

FIG. 9 is another cross sectional view of the configuration of the conventional substrate; and

FIG. 10 is a cross sectional view of a configuration of a conventional heat pipe.

### DETAILED DESCRIPTION OF THE PREFERRED EMBODIMENTS

### Embodiment

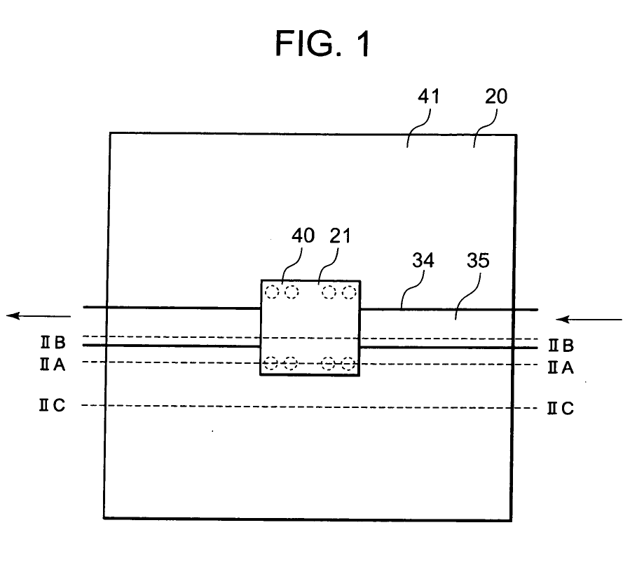

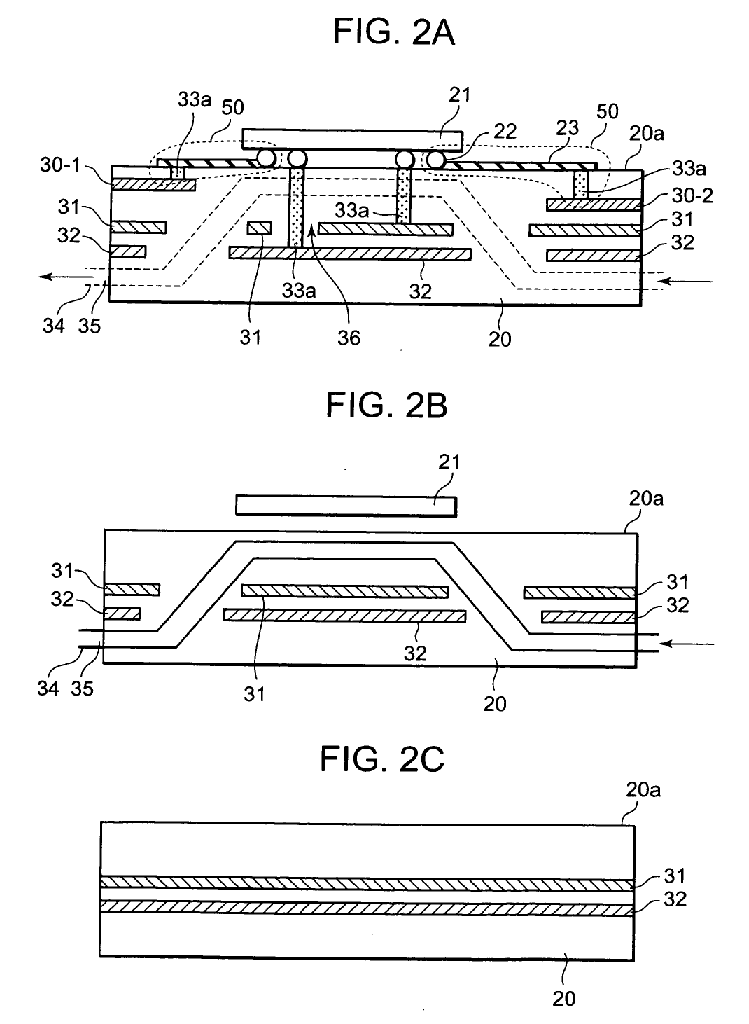

Hereunder, there will be described a wiring substrate in this embodiment with reference to FIGS. 1 and 2. FIG. 1 is a top view of a configuration of the wiring substrate (hereunder, to be referred to simply as the substrate) on which a semiconductor integrated circuit (hereunder, to be referred to simply as the IC chip) is mounted. FIG. 2A is a cross sectional view taken on line IIA-IIA of FIG. 1 with respect to part of the heat pipe 34. In FIG. 2A, the heat pipe 34 is shown as a perspective view. FIG. 2B and FIG. 2C are also cross sectional views taken on lines IIB-IIB and IIC-IIC of FIG. 1. In FIG. 1, signal layers 30-1 and 30-2 except for their major portions, etc. are omitted.

An IC chip 21 that is an electronic part is mounted on a surface 20a, which is the first main surface of the substrate 20 (the top surface of the substrate 20). The IC chip 21 is mounted in an area 40 on the surface 20a.

The IC chip 21 is a BGA (Ball Grid Array) type one having solder balls on the back surface and used to connect the power supply, ground, and signal layers to each another. On the surface 20a of the substrate 20 are formed pads corresponding to the solder balls 22 of the IC chip 21 respectively. Those pads are to be connected to the solder balls 22 of the IC chip respectively when the IC chip 21 is mounted on the substrate 20. And as needed, a wiring 23 may be formed so as to connect the pads electrically to vias 33a (to be described later).

The substrate 20 also has signal layers 30-1 and 30-2, a power supply layer 31, and a ground (GND) layer 32 deposited sequentially in this order on the mounting surface 20a. Each of those layers (wiring layers) has a conductor pattern and those conductor patterns are stacked with. for example, an insulation substrate therebetween to assure their insulation properties respectively. In other words, an insulation layer is formed between each pair of the signal layers 30-1 and 30-2, the power supply layer 31, and the GND layer 32. The wiring layers having those conductor patterns are connected electrically to the IC chip 21 through the solder balls 22, respectively.

The signal layers 30-1 and 30-2 are wiring layers having signal wiring conductor patterns used to input/output data, control signals, etc. respectively. The power supply layer 31 is a wiring layer having a conductor pattern for supplying a power. The GND layer 32 is a wiring layer having a conductor pattern for grounding. On each of the power supply layer 31 and the GND layer 32 is formed a conductor pattern, which is approximately formed all over the layer except for the vias 33a and the heat pipe 34 to be described later. The pattern is connected to the power supply potential and reference potential points (ground or ground potential). The substrate 20 has a plurality of the vias 33a. Those vias 33a are used to connect the conductor patterns of the signal layers 30-1 and 30-2, the power supply layer 31, and the GND layer 32 electrically to the pads respectively. The vias 33a are formed as blind vias here. A blind via means a via connected only to one side surface of the substrate 20. For example, the blind via for connecting a signal line formed on the signal layer 30-1 electrically to a pad is formed by forming a hole in an insulation substrate provided on a signal wiring pattern (conductor pattern) formed on the signal layer 30-1, then by filling, for example, a plating conductor in the hole. As a result, solder balls used for signals come to be connected electrically to a signal wiring pattern formed on the signal layer 30-1 through the pads and wiring 23. In the power supply layer 31 are formed clearance halls 36. A clearance hall means an opening provided in a conductor pattern and used to prevent the connection to such a via 33a assumed as a blind via or the like. In such a way, the clearance hall 36 prevents the connection that might otherwise be made between the power supply layer 31 and the GND layer 32 through the vias 33a.

As described above, FIG. 2B shows a cross sectional view taken on line IIB-IIB of FIG. 1 with respect to a position at which the heat pipe 34 is provided. FIG. 2C shows a cross sectional view taken on line IIC-IIC of FIG. 1 with respect to a position on this side of the mounted IC chip. As shown in FIG. 2B, on the line IIB-IIB exists a breaking point of a conductor pattern, which is passed by the heat pipe 34. And as shown in FIG. 2C, on the line IIC-IIC are formed the power supply layer 31 and the GND layer 32 that are continued on respectively in the right-left direction.

The substrate 20 has a built-in heat pipe 34, which is a cooling pipe 34 for flowing a coolant 35 in the layers provided in the substrate 20. The heat pipe 34 absorbs the heat generated from the IC chip 21.

As shown in FIG. 1, the heat pipe 34 has a predetermined width and is extended from one end to the other of the substrate 20. Here, the width of the heat pipe is determined so as to be fit in the width of the IC chip 21 and not to become an obstacle for the vias 33a, etc. However, the width may not be limited only to that; for example, the forming places of the vias 33a, etc. may be changed to form the heat pipe 34 at the same width approximately as that of the IC chip 21 or wider than the IC chip 21. In this case, the cooling effect can further be improved without increasing the number of the heat pipes 34. In FIG. 1, the heat pipe is formed linearly and extended from one end of the substrate to the other end that faces the one end. However, the shape of the heat pipe 34 may not be limited only to that; if the heat pipe is extended so as to pass the area 40 in which the IC chip 21 is mounted, the heat pipe 34 may be bent.

Unlike in the outside area 41 of the area 40, the heat pipe 34 is passed near the mounting surface 20a in the area 40. Concretely, the heat pipe 34 is passed near the mounting surface 20a of the GND layer 32 in the mounting area 40, that is, near the mounting surface 20a. And the heat pipe 34 is passed on the opposite side of the mounting surface 20a of the GND layer 32 at least at part of the outside area 41, that is, farther from the mounting surface 20a. More concretely, the heat pipe 34 is disposed so that its distance from the mounting area 40 with respect to the mounting surface 20a becomes shorter than its distance from the area 41 provided outside the mounting area 41. In FIG. 2B, the heat pipe 34 is disposed lower than the GND layer 32 at both sides of the substrate 20 and higher than the power supply layer 31 at a portion facing the center of the substrate 20 (that faces the mounting area 40). More concretely, in the mounting area 30, the upper portion of the heat pipe 34 is passed over the signal layer 30-1. Consequently, only one insulation layer is formed over the heat pipe 34 in the mounting area 40, except for the pads and wiring 23 formed on the substrate 20. In such a way, the heat pipe 34 is passed near the mounting surface 20a in the mounting area 40 and near the back side of the IC chip 21 when it is mounted on the substrate 20.

And as shown in FIGS. 2A and 2B, the heat pipe 34 has a plurality of bending points, as well as a predetermined slope, which is extended from one end of the substrate 20 toward the center thereof. In other words, the heat pipe 34 has a predetermined slope near the mounting area 40 in the outside area 41. More concretely, the slope of the heat pipe 34 is formed so that the distance from the mounting surface 20a increases from the mounting area 40 toward the outside of the mounting area 40. The heat pipe 34 is also formed so as to cross a plurality of layers of the substrate 20. Here, the plurality of layers of the substrate 20 are the GND layer 32, the power supply layer 31, signal layers 30-1 and 30-2, as well as insulation layers or the like formed between each pair of those layers. In other words, the heat pipe 34 is formed so as to be closest to the mounting surface 20a just under the IC chip 21 and closer to the opposite surface (back side of the substrate 20) of the mounting surface 20a as it goes farther from the IC chip 21. The heat pipe 34 passing the mounting area 40 is in parallel to the mounting surface 20a. This means that the heat pipe 34 is partially passed in parallel to the mounting surface 20a when facing the mounting area 40. Consequently, the heat pipe 34 can cool down the whole IC chip 21 effectively. Furthermore, the heat pipe 34 can cool down the IC chip 21 nearly in uniform.

The heat pipe 34 is formed near the power supply layer 31 or GND layer 32 at a portion facing the outside area 41. Here, the heat pipe 34 passing the periphery (an end portion of the substrate 20) of the outside area 41 comes to be passed in parallel to the GND layer 32 under the GND layer 32. As described above, a conductor pattern is formed approximately all over the GND layer 32. In this embodiment, the power supply layer 31 and the GND layer 32 are structured similarly. However, only one of the power supply layer 31 and the GND layer 32 may be structured to have a conductor pattern formed approximately all over itself.

As described above, the heat pipe 34, when passing a layer positioned near the mounting surface 20a in the substrate 20, enters the substrate 20 from the bottom side of the GND layer 32, passes through the GND layer 32 to the top surface of the power supply layer 31, then goes near the mounting surface 20a near the IC chip 21 mounted on the substrate 20. After this, the heat pipe 34 passes through the GND layer 32 and the power supply layer 31 and goes into a layer formed under the layer 31 in the outside area 41 in which the IC chip 21 is not mounted, then exits the GND layer 32 from its back side. In such a way, the heat pipe 34 passes the back side of the GND layer 32 at part of the outside area 41 formed in the substrate 20. As a result, the coolant 35 flowing in the heat pipe 34 comes to be supplied from the back side of the GND layer 32 into the layer formed above the substrate 20 around the IC chip 21, then to exit the back side of the GND layer 32. In such a way, a coolant channel is formed so as to pass the layer under the GND layer at part of the outside area 41. This completes the description for the substrate 20 structured as described above in this embodiment.

Next, there will be described how to release the heat from the object package through the heat pipe 34 formed as described above. For example, it is premised here that the coolant 35 flows as denoted by the arrows in FIGS. 1 and 2, that is, from right to left in the heat pipe 34. At first, the coolant 35 is supplied to the heat pipe 34 disposed under the GND layer 32 in the outside area 41. Then, the coolant 35 in the heat pipe 34 passes the layer formed above the substrate 20 around the IC chip 21 to flow around the back side of the IC chip 21. This means that the coolant 35 flows near the mounting surface 20a in the mounting area 40. As a result, the heat generated from the IC chip 21 is absorbed by the coolant 35 flowing in the heat pipe 34 around the back side of the IC chip 21 on the substrate 20 through the solder balls 22 and released outside the package. Consequently, the heat resistance from the IC chip 21, which is a heat generation source, can be reduced, thereby the heat radiation effect is improved.

On the other hand, there is no heat source element on the opposite surface of the mounting area 20a, so heat radiation from here to outside can be expected. In this embodiment, the heat pipe 34 is disposed near the opposite surface of the mounting surface 20a in the outside area 41. Consequently, in addition to the heat radiation just by the coolant 35, it is also expected that the heat can be released by the heat pipe 34 effectively from the opposite surface of the mounting surface 20a. In addition, in the outside area 41, the heat pipe 34 is passed under (near) the GND layer 32, so the heat radiation can be made effectively just by lowering the thermal resistance between the GND layer 32 that is part of the heat radiation path and the IC chip 21.

As described above, in the substrate 20 in this embodiment, the coolant 35 flows near the IC chip 21. Consequently, the coolant 35 can absorb the heat generated from the IC chip 21 and the I/O device. Furthermore, in other portions, the coolant 35 flows under the GND layer 32. Consequently, even when the heat absorbed by the coolant 35 is radiated, the heat comes to be released to the layer formed above the GND layer 32. And the heat to be released to the layer formed above the GND layer 32 can be suppressed. In other words, according to the substrate 20 in this embodiment, the heat generated from the IC chip 21 can be released satisfactorily, thereby the cooling effect of the substrate 20 is improved satisfactorily.

In the heat pipe system employed in this embodiment, the heat pipe 34 is passed near the IC chip 21 in the substrate 20. Consequently, the structure of the heat pipe system can be reduced in size and improved in heat radiation efficiency more than any of conventional heat radiation methods and systems in each of which a heat spreader is just added to the IC chip 21 to realize the heat radiation from the package or a heat pipe is just passed just in the substrate. Furthermore, because the heat pipe 34 is laid around flexibly in the substrate 20 in this embodiment, the heat pipe 34 can be formed near the mounting surface only in necessary places. Consequently, the conductor pattern of each layer formed near the mounting surface 20a, that is, the conductor patterns of the signal layers 30-1 and 30-2 can be improved in laying flexibility.

Furthermore, the IC chip 21 is generally provided with an I/O device at the outer periphery of the IC chip 21.

Consequently, the wiring 23 extended from the IC chip 21 on the substrate 20 is pulled out to the outside area 41 of the substrate 20 from the outer periphery of the IC chip 21. At this time, as shown in FIG. 2A, vias 33a are provided to connect the conductor patterns disposed in the signal layers 30-1 and 30-2 electrically to the solder balls 22. Here, a wiring pulling-out device 50 is used to connect the pads corresponding to the solder balls 22 electrically to the signal layers 30-1 and 30-2. And in order to improve the wiring property of the substrate 20, such vias 33a should be disposed just under the solder balls 22. This means that those vias 33a should be disposed just under those pads.

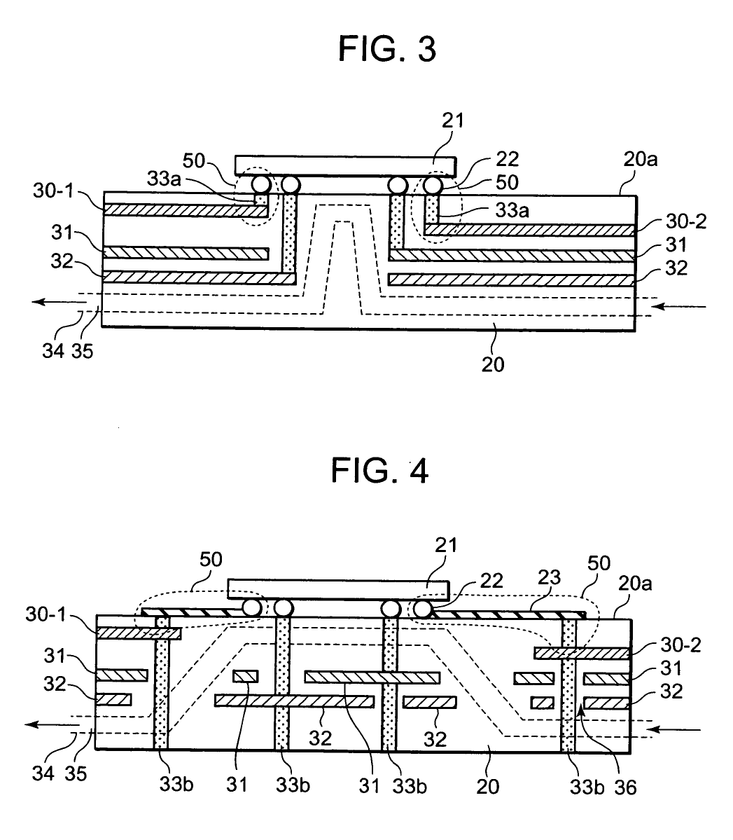

Next, there will be described such an example in which the vias 33a are formed just under the pads with reference to FIG. 3. FIG. 3 shows a cross sectional view of a configuration of the substrate 20 having those vias 33a formed just under the pads. FIG. 3 is equivalent to the cross sectional view taken on line IIA-IIA of FIG. 1.

As shown in FIG. 3, if the vias 33a are formed just under the pads respectively as described above, part of the conductor pattern in each layer comes to be formed in the mounting area 40. This means that the conductor pattern in each layer is also formed partially just under the IC chip 21. And just like in the above case, the heat pipe 34 is passed near the mounting surface 20a in the mounting area 40 and far away from the mounting surface 20a in the outside area 41. Furthermore, the heat pipe 34 is passed in parallel to the mounting surface 20a in a portion that is not in contact with the solder balls 22 of the mounting area 40, that is, inside the area where the pads of the mounting area 40 are formed. This means that a portion of the heat pipe 34, which is passed in parallel to the mounting area 20a in a portion facing the mounting area 40, is laid to avoid the pads. In other words, in the center of the mounting area 40, the heat pipe 34 is passed in parallel to the mounting area 20a. And in the above portion, the heat pipe 34 is passed near a portion closest to the mounting surface 20a. In addition to the heat radiation effect described above, such a structure could improve the wiring property of the substrate 20. Concretely, in case of the substrate 20 shown in FIG. 2, the conductor patterns of the signal layers 30-1 and 30-2 are not formed just under and at the outer periphery of the IC chip 21. On the other hand, in case of the substrate 20 shown in FIG. 3, the conductor patterns of the signal layers 30-1 and 30-2 can be formed at the outer periphery just under the IC chip 21, as well as in part of the area just under the IC chip 21.

Next, there will be described another example of the substrate 20 with reference to FIG. 4. FIG. 4 shows a cross sectional view of a configuration of the substrate 20 having through-vias 33b. FIG. 4 is equivalent to the cross sectional view taken on line IIA-IIA of FIG. 1.

In FIG. 4, vias are formed as through-vias (through-holes) 33b. A through-via 33b is a via connected to both surfaces of the object substrate 20. In other words, the through-via 33b is formed by filling such a plating conductor in an object hole that goes through all the layers of the substrate 20. If a conductor pattern (not shown) is formed on the back surface of the substrate 20, it is also possible to connect the pads to the conductor pattern formed on the back surface of the substrate 20 through the through-vias 33b formed as described above. For example, the through-vias 33b may be used to connect the power supply terminals (pads) provided in the mounting area 40 to the conductor pattern formed on the second main surface (back surface of the substrate 20) facing the mounting surface 20a. Then, for example, a conductor pattern that can avoid the through-via 33b in each layer of the substrate 20 is formed by forming such a clearance hole 36 or the like.

In such a way, blind vias or through-vias 33b may be formed as vias. If many through-vias 33b are formed, however, many clearance holes 36 are required in the GND layer 32. Consequently, the blind vias should be employed preferentially over the through-vias 33b. This makes it possible to form the conductor pattern on the GND layer 32 in a wider range. As a result, the package comes to be assured for more stable driving. Furthermore, this makes it possible to suppress the heat radiation from the heat pipe 34 into the layer formed above the GND layer 32.

As described above, the substrate 20 uses the coolant 35 for cooling down one IC chip 21. However, the cooling method can be replaced with another freely. For example, if cooling by the coolant 35 flowing in the heat pipe 34 is much above what is necessary, the same coolant 35 may also be used for cooling down a plurality of IC chips 21. In other words, the cooling system may be applied for not only a single IC chip 21, but also for a plurality of IC chips 21.

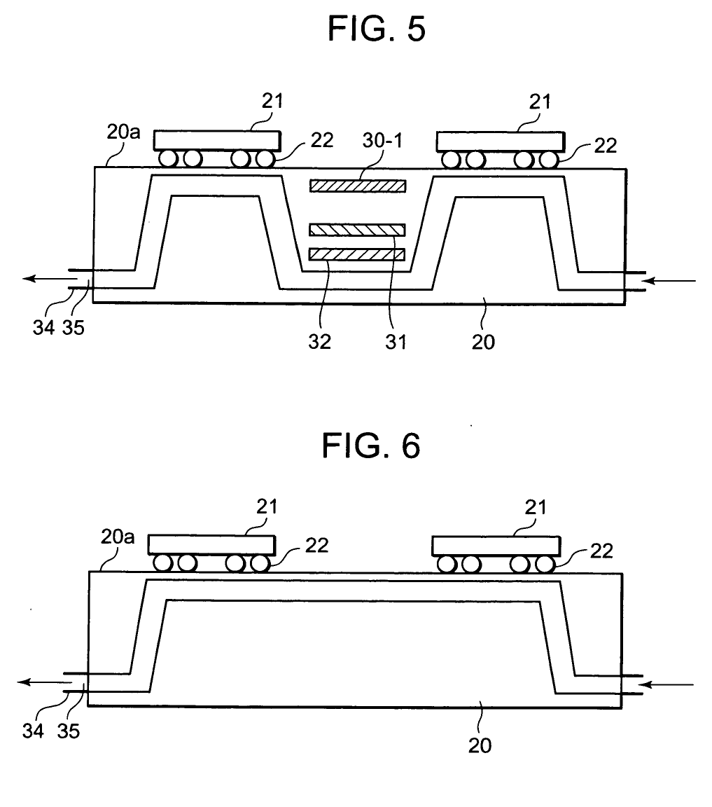

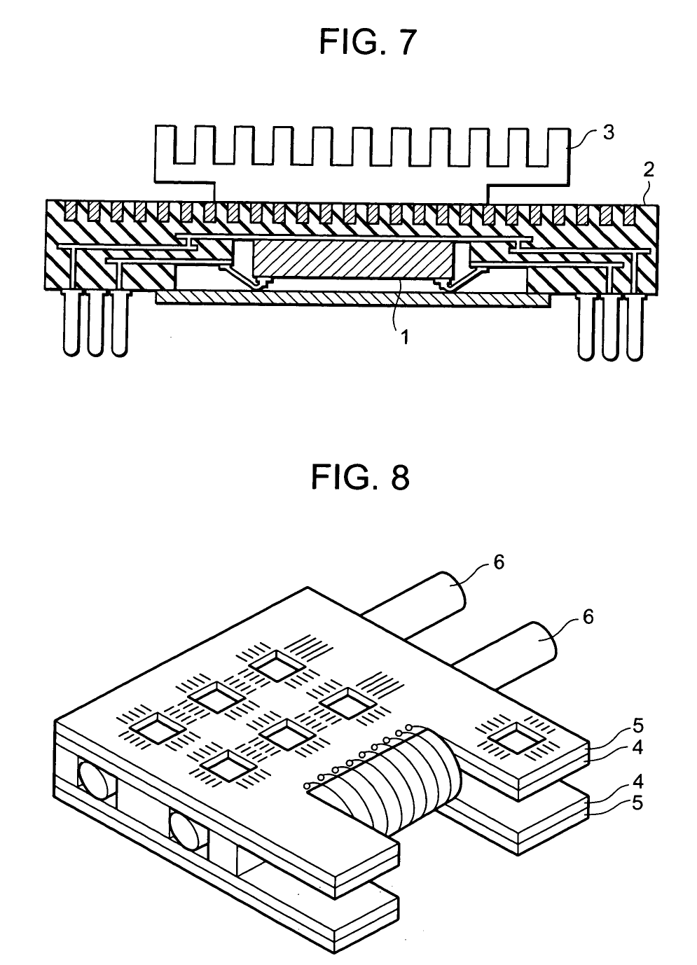

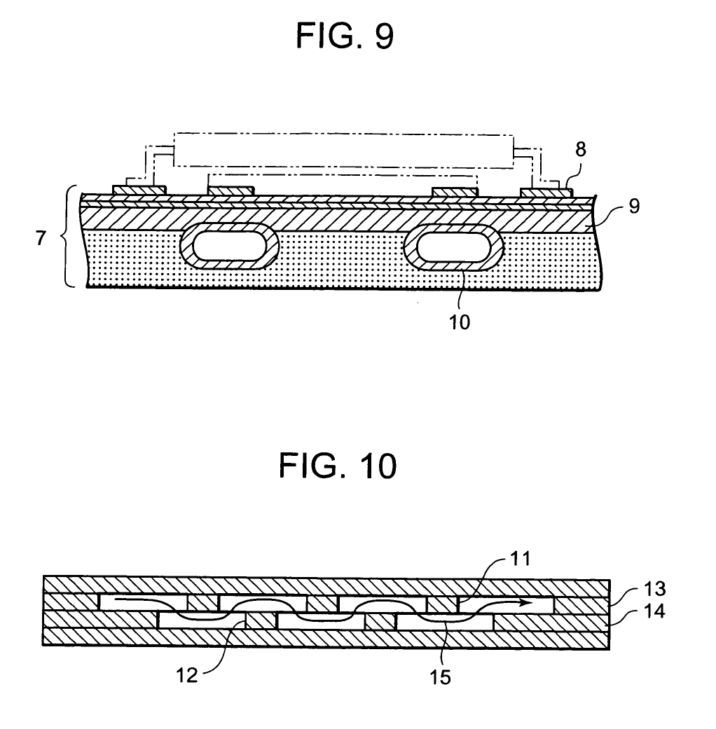

Next, there will be described a substrate 20 on which two IC chips 21 are mounted with reference to FIGS. 5 and 6. FIG. 5 shows a cross sectional view of a configuration of the substrate 20 on which two IC chips 21 are mounted. FIG. 6 shows a cross sectional view of another configuration of the substrate 20 on which two IC chips 21 are mounted.

In FIGS. 5 and 6, only major portions are shown; other portions are omitted.

The substrate 20 shown in FIG. 5 has the power supply, GND, and signal wirings between the two adjacent IC chips. Concretely, there are provided conductor patterns of the signal layer 30-1, the power supply layer 31, and the GND layer 32 between those two IC chips 21. In this case, the heat pipe 34 is passed under those elements between the two IC chips 21. In other words, the heat pipe 34 is passed under the GND layer 32 between the two IC chips 21. And in each mounting area 40, the heat pipe 34 is passed near the mounting surface 20a. In the outside area 41, however, the heat pipe 34 may be formed just like in the substrate 20 shown in FIG. 2, etc.

The substrate 20 shown in FIG. 6 has none of the power supply, GND, and signal wirings between the two adjacent IC chips 21. In other words, there is no conductor pattern formed for any of the signal layers 30-1 and 30-2, the power supply layer 31, and the GND layer 32 between the two IC chips 21. In this case, the heat pipe 34 may be laid so as to connect the underside of the mounting area 40 of the IC chips 21 on the same plane. In other words, the heat pipe 34 is passed near the mounting surface 20a between one mounting area 40 and another mounting area 40. And in this area, the heat pipe 34 is passed in parallel to the mounting surface 20a. This means that the heat pipe 34 is passed near the mounting surface 20a even between the two IC chips 21. This is different from the case shown in FIG. 5. In such away, the heat pipe 34 is passed near the mounting surface 20a even in the outside area 41 between the adjacent IC chips 21. In other outside areas 41, the heat pipe 34 may be laid just like the substrate 20 shown in FIG. 2, etc.

As described above, the number of heat pipes 34 to be formed in the substrate 20 can be reduced by using the coolant 35 flowing in one heat pipe 34 for a plurality of IC chips 21. And for example, the flexibility for designing conductor patterns can also be improved. Furthermore, the amount of the coolant 35 can be suppressed. It is also possible to use the same coolant 35 flowing in a plurality of heat pipes 34 for cooling down one IC chip, of course. In this case, the cooling effect can further be improved. The coolant 35 used in this embodiment may be any of liquids and gases that can absorb such a heat. If the heat pipe 34 is provided with enough thermal conductivity, no coolant is required.

In this embodiment, the signal layers 30-1 and 30-2, the power supply layer 31, and the GND layer 32 are connected electrically to the IC chip 21. Layers to be connected to the IC chip 21 may be replaced with others as needed. Furthermore, although the signal layers 30-1 and 30-2, the power supply layer 31, and the GND layer 32 are formed sequentially in this order on the mounting surface 20a, the forming order may be changed as needed.

The wiring substrate of the present invention can apply to any substrate on which electronic parts such as IC chips are to be mounted, for example, printed substrates, ceramic substrates, etc. Furthermore, the wiring substrate of the present invention can also apply to semiconductor package substrates.

What is claimed is:

1. A wiring substrate having a built-in heat pipe,
wherein the wiring substrate has:
a mounting area provided on one main surface of the wiring substrate and used to mount an electronic part; and
a heat pipe formed so that its distance from the mounting area with respect to the main surface becomes shorter than its distance from an area provided outside the mounting area.

2. The wiring substrate according to claim 1,
wherein the heat pipe has a slope extended from the mounting area to the outside of the mounting area so as to increase its distance from the one main surface of the wiring substrate.

3. The wiring substrate according to claim 1,
wherein the heat pipe has a portion formed in parallel to the main surface of the wiring substrate at a portion facing the mounting area.

4. The wiring substrate according to claim 1,
wherein the heat pipe is formed near a power supply layer or ground layer at a portion facing the area outside the mounting area.

5. The wiring substrate according to claim 1,
wherein the wiring substrate has a plurality of wiring layers and a plurality of insulation layers.

6. The wiring substrate according to claim 1,
wherein the wiring substrate includes a power supply terminal provided in the mounting area; and
wherein the power supply terminal is connected electrically to a conductor formed at a second main surface side facing the main surface.

7. The wiring substrate according to claim 3,
wherein the portion formed in parallel to the main surface at the portion facing the mounting area is formed by avoiding a pad of the electronic part disposed in the mounting area in the heat pipe.
